(19) United States
(12) Patent Application Publication
(10) Pub. No.: US 2009/0121353 A1
(43) Pub. Date: May 14, 2009

(54) DUAL DAMASCENE BEOL INTEGRATION WITHOUT DUMMY FILL STRUCTURES TO REDUCE PARASITIC CAPACITANCE

(76) Inventors: Deepak A. Ramappa, Cambridge, MA (US); Eden M. Zielinski, Wappingers Falls, NY (US)

Correspondence Address: TEXAS INSTRUMENTS INCORPORATED, P O BOX 655474, M/S 3999, DALLAS, TX, 75265, US

(21) Appl. No.: 11/939,040

(22) Filed: Nov. 13, 2007

(51) Int. Cl. H01L 21/768; H01L 23/52

(52) U.S. Cl. 257/751; 438/653; 257/E21.584; 257/E23.141

(57) ABSTRACT

In accordance with the invention, there are methods of making semiconductor devices. The method can include forming a hard mask layer over a dielectric layer, forming a via through the hard mask layer and the dielectric layer, and depositing an anti-reflective coating in the via and over the hard mask layer. The method can also include etching a trench through the hard mask layer, etching a dummy fill pattern in the hard mask layer to a desired thickness, and etching the trench through the dielectric layer and the dummy fill through the hard mask layer and in the dielectric layer. The method can further include depositing copper in the via and in the trench and removing excess copper using chemical mechanical polishing, wherein the dummy fill in the dielectric layer is of desired reduced depth.

### DESCRIPTION OF THE INVENTION

1. Field of the Invention

The subject matter of this invention relates to methods of fabricating semiconductor devices. More particularly, the subject matter of this invention relates to the methods of integrating shallow dummy fill features in BEOL to reduce parasitic capacitance,

2. Background of the Invention

Dummy fill features in back end of line (BEOL) interconnect (IC) system help reduce chemical mechanical polishing non-uniformity and also provide mechanical support between porous inter level dielectric layers. However, dummy fill features add parasitic capacitance to the total capacitance of interconnects. Furthermore, with scaling, the parasitic capacitance of the dummy fill features is proving to be detrimental to RF circuit BEOL. Therefore, there is a need to reduce/eliminate parasitic capacitance without eliminating the use of dummy structures for chemical mechanical polishing. Currently, one of the strategies used to reduce parasitic capacitance is to increase the interconnect spacing between the lines by optimizing the layout, as parasitic capacitance is inversely proportional to the interconnect spacing between the lines. Since, parasitic capacitance is especially critical in signal lines and clock lines, IC designers place these types of lines in areas where they can afford more spacing. However, optimizing by routing lines with thinner metal line densities can result in an increase in the line length, which in turn can be detrimental to the circuit speed. Furthermore, this type of design optimization is getting harder as design rules are shrinking. Hence, there is a need to find new ways to reduce parasitic capacitance.

Accordingly, the present invention solves these and other problems of the prior art by providing methods of integrating shallow dummy fill features in BEOL to reduce parasitic capacitance.

### SUMMARY OF THE INVENTION

In accordance with the present teachings, there is a method of making a semiconductor device. The method can include forming a first hard mask layer having a first thickness over a dielectric layer and forming a second hard mask layer having a second thickness over the first hard mask layer, wherein the second thickness is greater than the first thickness. The method can also include forming a trench pattern in the second hard mask layer, depositing an anti-reflective coating in the trench pattern and over the second hard mask layer, and forming a via pattern and a dummy fill pattern in a resist layer disposed over the anti-reflective coating. The method can further include etching the via pattern through the first hard mask layer and the dummy fill pattern in the second hard mask layer and etching the via pattern through the dielectric layer and the dummy fill pattern in the second hard mask layer, wherein the dielectric layer has an etch selectivity approximately eight to ten times that of the first hard mask layer and the second hard mask layer. The method can also include etching the trench through the dielectric layer and the dummy fill through the second hard mask layer, first hard mask layer and in the dielectric layer, depositing copper in the via and the trench, and removing excess copper by chemical mechanical polishing, wherein the dummy fill in the dielectric layer is of a desired reduced depth.

According to another embodiment of the present teachings, there is a method of making a semiconductor device. The method can include forming a hard mask layer over a dielectric layer, forming a via through the hard mask layer and the dielectric layer, and depositing an anti-reflective coating in the via and over the hard mask layer. The method can also include etching a trench through the hard mask layer, etching a dummy fill pattern in the hard mask layer to a desired thickness, and etching the trench through the dielectric layer and the dummy fill through the hard mask layer and in the dielectric layer, wherein the dielectric layer has an etch selectivity approximately eight to ten times that of the hard mask layer. The method can further include depositing copper in the via and in the trench and removing excess copper using chemical mechanical polishing, wherein the dummy fill in the dielectric layer is of desired reduced depth.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIGS. 1A-1J illustrate an exemplary method of making a semiconductor device, according to various embodiment of the present teachings.

FIGS. 2A-2H illustrate another exemplary method of making a semiconductor device, in accordance with various embodiments of the present teachings.

FIGS. 3A and 3B show schematic illustration of exemplary dummy fill feature and interconnect line.

FIG. 3C is a graph showing normalized capacitance as a function of dummy fill thickness.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 100” can assume negative values, e.g. −1, −2, −3, −10, −20, −30, etc.

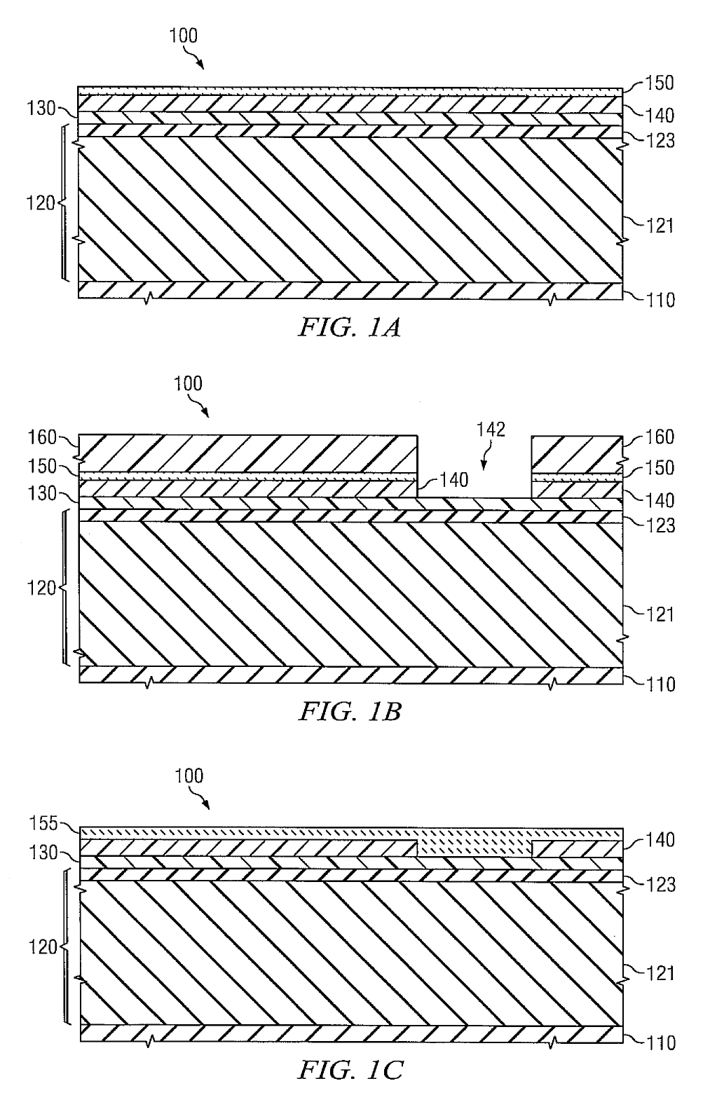

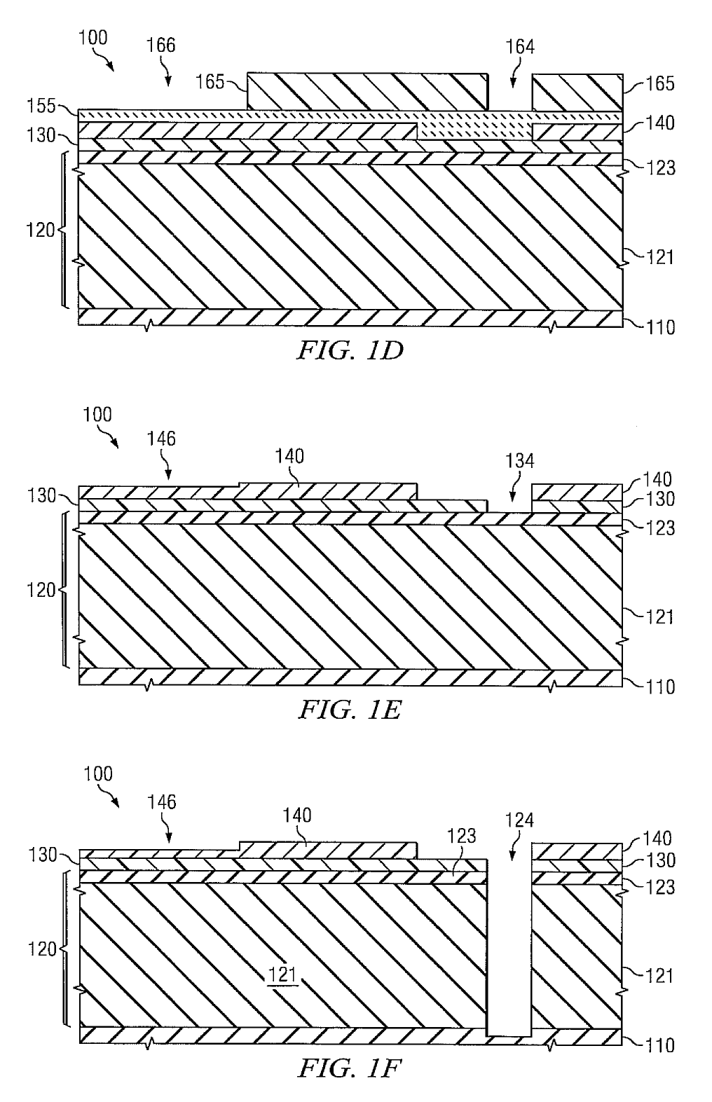

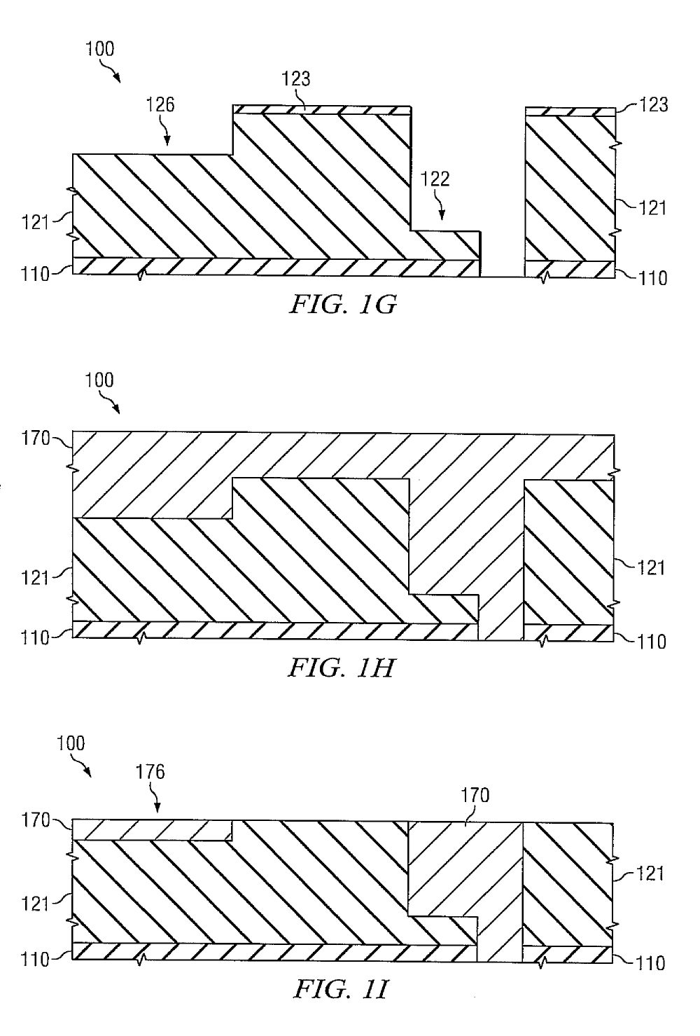

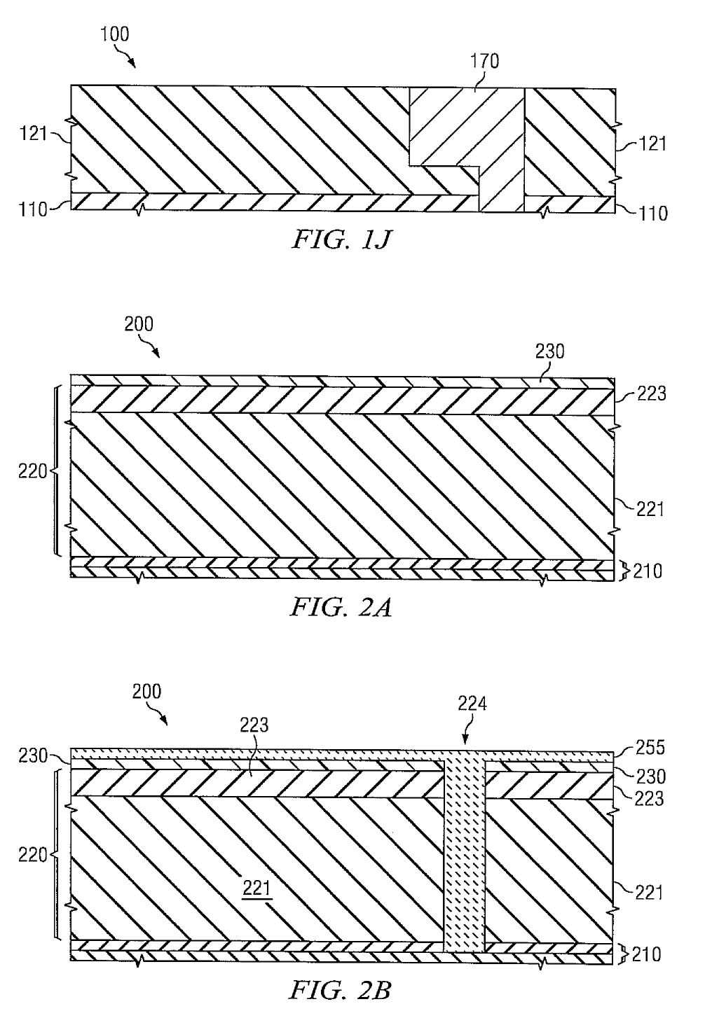

FIGS. 1A-1J illustrate an exemplary method of making a semiconductor device 100. The method can include forming a first hard mask layer 130 having a first thickness over a dielectric layer 120, as shown in FIG. 1A. In various embodiments, the dielectric layer 120 can include any interlevel or intralevel “low-k” dielectric that can be employed in the back end of line (BEOL) integration, including, but not limited to, one or more of silicon oxide, organo silicate glass (OSG), fluorine-doped silicate glass (FSG), tetraethyl orthosilicate (TEOS), carbon doped silicon oxide, polyamides, fluorinated polyamides, methyl silsesquioxane (MSSQ), hydrogen silsesquioxane (HSSQ), parylene-N, parylene-F, aromatic thermosets, Teflon® AF, and benzocyclobutenes. In an exemplary case, the dielectric layer 120 can have a bi-layer structure as shown FIG. 1A, wherein the first layer 121 can include an ultra low-k dielectric, while the second layer 123 over the first layer 121 can include any other dielectric. The dielectric layer 120 can be formed by any suitable method such as, for example, chemical vapor deposition (CVD), low pressure chemical vapor deposition (LPCVD), plasma enhanced chemical vapor deposition (PECVD), and atomic layer deposition (ALD). In various embodiments, the dielectric layer 120 can have a thickness from about 1000 Å to about 4000 Å. In some embodiments, the dielectric layer 120 can be formed over an etch stop layer 110, as shown in FIG. 1A. The etch stop layer 110 can include one or more of silicon carbide, oxygen doped silicon carbide, nitrogen doped silicon carbide, silicon nitride, oxygen doped silicon nitride, carbon doped silicon nitride, and oxygen and carbon doped silicon nitride. In various embodiments, the etch stop layer 110 can have a thickness from about 100 Å to about 500 Å. The method can also include forming a second hard mask layer 140 having a second thickness over the first hard mask layer 130, wherein the second thickness is greater than the first thickness. In various embodiments, the first hard mask layer 130 can have a thickness from about 100 Å to about 300 Å and the second hard mask layer 140 can have a thickness from about 500 Å to about 1500 Å. In various embodiments, the first hard mask layer 130 can serve as one or more of an etch stop layer and a capping layer. In some embodiments, the first hard mask layer 130 and the second hard mask layer 140 can include one or more of silicon carbide, oxygen doped silicon carbide, nitrogen doped silicon carbide, silicon nitride, oxygen doped silicon nitride, carbon doped silicon nitride, and oxygen and carbon doped silicon nitride The first hard mask layer 130 and the second hard mask layer 140 can be deposited by any suitable method, including, but not limited to, chemical vapor deposition (CVD), low pressure chemical vapor deposition (LPCVD), plasma enhanced chemical vapor deposition (PECVD), atmospheric pressure chemical vapor deposition (APCVD), physical vapor deposition (PVD), and atomic layer deposition (ALD). In some embodiments, a layer of anti-reflective coating 150 can be formed over the second hard mask layer 140. In various embodiments, the anti-reflective coating 150 can include one or more of an organic bottom anti-reflective coating (BARC) layer, an inorganic BARC layer, and a hybrid organic-inorganic BARC layer. One of ordinary skill in the art would know that with every technology node, the device size shrinks and with the decrease in the device size, the thickness of the various layers, such as, for example, the dielectric layer 120, the first hard mask layer 130, the second hard mask layer 140, and the anti-reflective coating 150 can also decrease proportionately.

The method of making a semiconductor device 100 can further include forming a trench pattern 142 in the second hard mask layer 140, as shown in FIG. 1B. The trench pattern 142 can be formed by first forming a resist layer 160 over the second hard mask layer 140. The step of forming a trench pattern 142 can also include forming a trench pattern lithographically in the resist layer 160 and etching a trench 142 through the hard mask layer 140 using the trench pattern in the resist layer 160, as shown in FIG. 1B. Any suitable chemical and/or physical etching process, such as, for example, fluorine based plasma etch and reactive ion etch can be used for the formation of trench pattern 142 in the second hard mask layer 140. The method of making a semiconductor device 100 can also include depositing an anti-reflective coating 155 in the trench pattern 142 and over the second hard mask layer 140, as shown in FIG. 1C. In various embodiments, the anti-reflective coating 155 can include one or more of an organic bottom anti-reflective coating (BARC) layer, an inorganic BARC layer, and a hybrid organic-inorganic BARC layer. The method can further include forming a via pattern 164 and a dummy fill pattern 166 in a resist layer 165 disposed over the anti-reflective coating 155, as shown in FIG. 1D. One of ordinary skill in the art would know that standard lithographic techniques can be used in the formation of via pattern 164 and the dummy fill pattern 166. The method can further include etching the via pattern 164 through the first hard mask layer 130 to form a via 134 in the first hard mask layer 130 and the dummy fill pattern 146 in the second hard mask layer 140, as shown in FIG. 1E. In various embodiments, since the etch selectivity of the first hard mask layer 130 and the second hard mask layer 140 are similar, about equal amount of first hard mask layer 130 and the second hard mask layer 140 are lost during this etching step. In other words the depth of the via 134 is about the same as that of the dummy fill pattern 146. The method of making a semiconductor device 100 can further include etching the via pattern 124 through the dielectric layer 120 and the dummy fill pattern 146 in the second hard mask layer 140, as shown in FIG. 1F. During this etch step, the dielectric layer 120 can have etch selectivity approximately eight to ten times that of the first hard mask layer 130 and the second hard mask layer 140. As a result, very small amount of trench hard mask thickness and dummy fill pattern 146 can be lost. One of ordinary skill in the art would know that the etch selectivity of the dielectric layer 120 can be changed by changing the density of the first hard mask layer 130 and the second hard mask layer 140 with respect to the dielectric layer 120; with greater the difference in the density, the higher the selectivity. The method can further include etching the trench 122 through the dielectric layer 120 and the dummy fill 126 through the second hard mask layer 140, first hard mask layer 130, and in the dielectric layer 120, as shown in FIG. 1G.

The method of making a semiconductor device can also include depositing copper 170 in the via 124 and the trench 122, as shown in FIG. 1H. The step of depositing copper 170 in the via 124 and the trench 122 can include forming a barrier layer (not shown) over the via 124 and the trench 122, depositing a copper seed layer (not shown) over the barrier layer (not shown) and depositing copper 170 in the via 124 and the trench 122 by electrochemical deposition. The method can further include removing excess copper 170 by chemical mechanical polishing, as shown in FIG. 1I, wherein the dummy fill 176 in the dielectric layer 120 is of a desired reduced depth. The reduced depth of the dummy fill 176 can result in reduced parasitic capacitance. In various embodiments, the dummy fill 176 can have a reduced depth of about 75% or more as compared to a dummy fill formed with conventional processing. In some embodiments, the dummy fill 176 can be totally removed as shown in FIG. 1J to eliminate parasitic capacitance due to dummy fill.

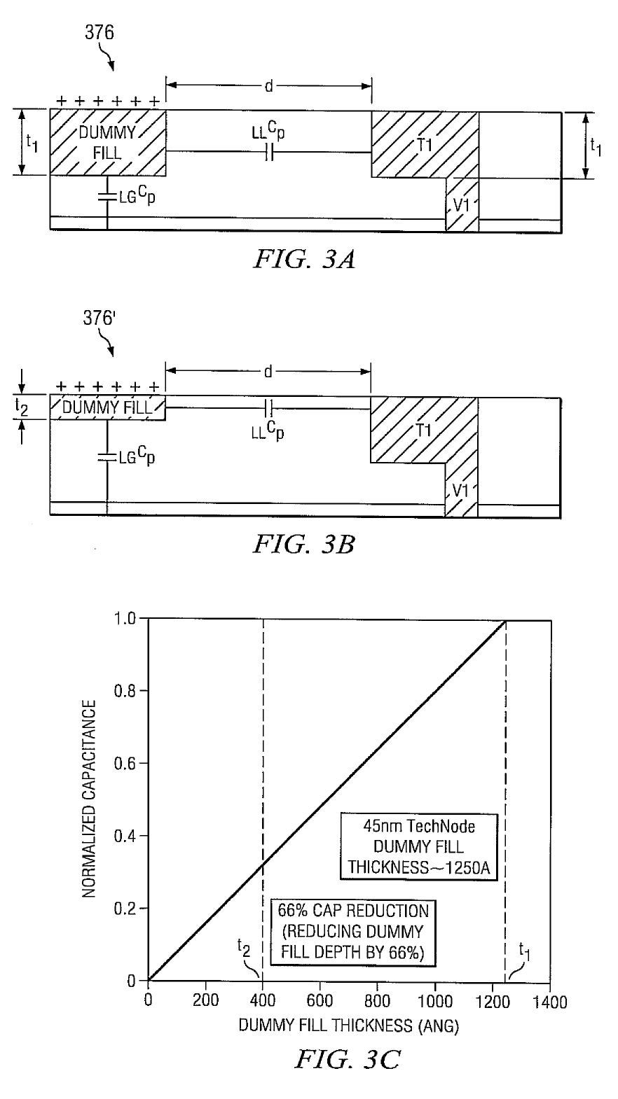

FIGS. 3A and 3B are schematic illustrations of dummy fills 376, 376′, each having a thickness of t₁ and t₂ (t₂<t₁) respectively at a distance d from an interconnect 372. The only difference between FIGS. 3A and 3B is the difference in thickness of the dummy fill metal structures 376 and 376′. Parasitic capacitance Cₚ due to the dummy fill 376, 376′ contributes to the total line to line capacitance (_{LL}Cₚ) and line to ground capacitance (_{LG}Cₚ), such that:

Cp ∝ A/d and A=t*L

where t is lesser of metal line thickness or dummy fill metal structure thickness, L is length of parallel metal structures, and d is the distance between metal line and dummy fill metal structure. FIG. 3C shows a calculated normalized capacitance contribution to line to line capacitance versus thickness of the dummy fill metal structure. The calculation is performed for a 1 μm length line. As can be seen in FIG. 3C, a 66% reduction in dummy fill metal structure depth can result in a 66% reduction in capacitance. Furthermore, parasitic capacitance Cp contribution of dummy fill metal structures can be completely eliminated by removing dummy fill.

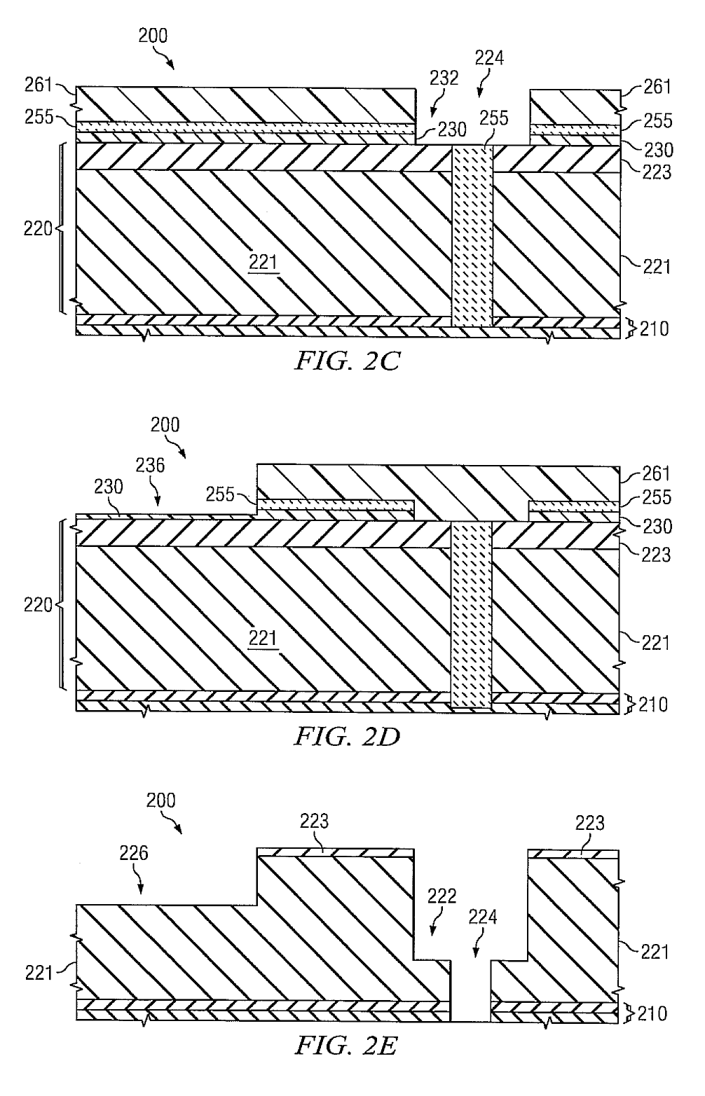

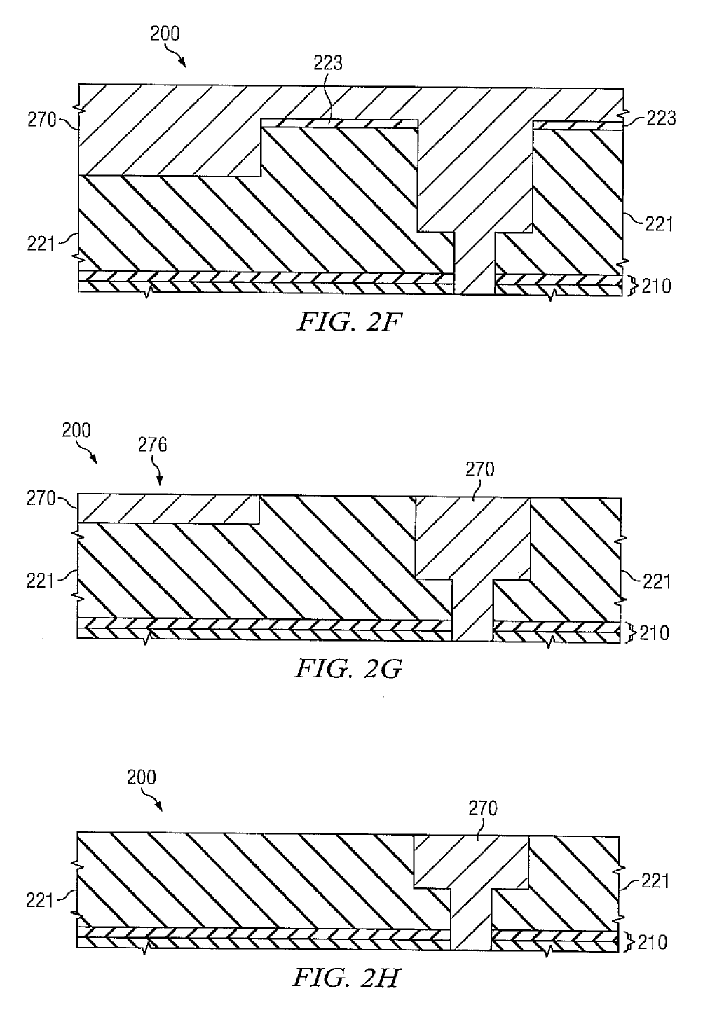

FIGS. 2A-2I illustrate another exemplary method of making a semiconductor device. The method can include forming a hard mask layer 230 over a dielectric layer 220. In various embodiments, the hard mask layer 230 can include one or more of silicon carbide, oxygen doped silicon carbide, nitrogen doped silicon carbide, silicon nitride, oxygen doped silicon nitride, carbon doped silicon nitride, and oxygen and carbon doped silicon nitride. In various embodiments, the hard mask layer 230 can have a thickness from about 100 Å to about 1500 Å. In some embodiments, the hard mask layer 230 can serve as one or more of an etch stop layer and a capping layer. In other embodiments, the dielectric layer 220 can include any interlevel or intralevel “low-k” dielectric that can be employed in the back end of line (BEOL) integration, including, but not limited to, one or more of silicon oxide, organo silicate glass (OSG), fluorine-doped silicate glass (FSG), tetraethyl orthosilicate (TEOS), carbon doped silicon oxide, polyamides, fluorinated polyamides, methyl silsesquioxane (MSSQ), hydrogen silsesquioxane (HSSQ), parylene-N, parylene-F, aromatic thermosets, Teflon® AF, and benzocyclobutenes. In various embodiments, the dielectric layer 220 can have a thickness from about 1000 Å to about 4000 Å. In an exemplary case as shown in FIG. 2A, the dielectric layer 220 can include a first dielectric layer 221 including an ultra low-k dielectric and a second dielectric layer 223 over the first dielectric layer 221, wherein the second dielectric layer 223 can include any other dielectric material, such as, for example, tetraethyl orthosilicate. In some embodiments, the dielectric layer 220 can be formed over an etch stop layer 210, as shown in FIG. 2A. In various embodiments, the etch stop layer 210 can have a thickness from about 100 Å to about 500 Å. In various embodiments, the etch stop layer 210 can include a bi-layer structure, wherein two layers can have different etch sensitivities. In some embodiments, the etch stop layer 210 can include one or more of silicon carbide, oxygen doped silicon carbide, nitrogen doped silicon carbide, silicon nitride, oxygen doped silicon nitride, carbon doped silicon nitride, and oxygen and carbon doped silicon nitride. One of ordinary skill in the art would know that with every new technology node, the device size shrinks and with the decrease in the device size, the thickness of the various layers, such as, for example, the dielectric layer 220, the hard mask layer 230, and the etch stop layer 210 can also decrease proportionately.

The method can further include forming a via 224 through the hard mask layer 230 and the dielectric layer 220 and depositing an anti-reflective coating 255 in the via 224 and over the hard mask layer 230, as shown in FIG. 2B. One of ordinary skill in the art would know that forming a via 224 can include forming a resist layer (not shown) over the hard mask layer 230, lithographically forming a via pattern in the resist layer, and etching a via through the hard mask layer 230 and the dielectric layer 220 using the via pattern in the resist layer (not shown). Any suitable chemical and/or physical etching such as reactive ion etching can be used for the formation of via 224. In various embodiments, the anti-reflective coating 255 can include one or more of an organic bottom anti-reflective coating material (BARC) layer, an inorganic BARC layer, and a hybrid organic-inorganic BARC layer. Any suitable method, such as, for example, spin coating can be used for the deposition of the anti-reflective coating.

The method of making a semiconductor device 200 can further include etching a trench 232 through the hard mask layer 230, as shown in FIG. 2C. The step of forming a trench can include forming a resist layer 261 over the anti-reflective coating 255, forming a trench pattern in the resist layer 261, and etching a trench 232 through the hard mask layer 230 using the trench pattern in the resist layer 261. Any suitable chemical and/or physical etching such as reactive ion etching can be used for the formation of trench 232. The method can also include etching a dummy fill pattern 236 in the hard mask layer 230 to a desired thickness, as shown in FIG. 2E. The method can further include etching the trench 222 through the dielectric layer 220 and the dummy fill 226 through the hard mask layer 230 and in the dielectric layer 220, wherein the dielectric layer 220 can have an etch selectivity approximately eight to ten times that of the hard mask layer 230. As a result of the difference in the etch selectivities of the hard mask layer and the dielectric layer, the dummy fill 226 formed in the dielectric layer 220 can be of significantly lower depth as compared to that formed by conventional processing. One of ordinary skill in the art would know that the etch selectivity of the dielectric layer 220 can be changed by changing the density of the hard mask layer 230 with respect to the dielectric layer 220; with greater the difference in the density, the higher the selectivity. The method of making a semiconductor device 200 can also include depositing copper 270 in the via 224 and in the trench 222 as shown in FIG. 2F and removing excess copper using chemical mechanical polishing, as shown in FIG. 2G wherein the dummy fill 276 in the dielectric layer 220 is of desired reduced depth. In various embodiments, the dummy fill 276 can have a reduced depth of about 75% or more as compared to a dummy feature formed with conventional processing. The reduced depth of dummy fill 276 can result in reduced parasitic capacitance contribution to the total line to line capacitance. In some embodiments, the dummy fill 276 can be substantially removed as shown in FIG. 2H, thereby substantially eliminating parasitic capacitance due to dummy fill 276, According to various embodiments, there are semiconductor devices formed by the disclosed methods.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” As used herein, the phrase “X comprises one or more of A, B, and C” means that X can include any of the following: either A, B, or C alone; or combinations of two, such as A and B, B and C, and A and C; or combinations of three A, B and C.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of making a semiconductor device, the method comprising:
forming a first hard mask layer having a first thickness over a dielectric layer;
forming a second hard mask layer having a second thickness over the first hard mask layer, wherein the second thickness is greater than the first thickness;
forming a trench pattern in the second hard mask layer;
depositing an anti-reflective coating in the trench pattern and over the second hard mask layer;
forming a via pattern and a dummy fill pattern in a resist layer disposed over the anti-reflective coating;
etching the via pattern through the first hard mask layer and the dummy fill pattern in the second hard mask layer;
etching the via pattern through the dielectric layer and the dummy fill pattern in the second hard mask layer, wherein the dielectric layer has an etch selectivity approximately eight to ten times that of the first hard mask layer and the second hard mask layer;
etching the trench through the dielectric layer and the dummy fill through the second hard mask layer, first hard mask layer and in the dielectric layer;
depositing copper in the via and the trench; and
removing excess copper by chemical mechanical polishing, wherein the dummy fill in the dielectric layer is of a desired reduced depth.

2. The method of claim 1, wherein the dielectric layer comprises one or more of silicon oxide, organo silicate glass (OSG), fluorine-doped silicate glass (FSG), tetraethyl orthosilicate (TEOS), carbon doped silicon oxide, polyamides, fluorinated polyamides, methyl silsesquioxane (MSSQ), hydrogen silsesquioxane (HSSQ), parylene-N, parylene-F, aromatic thermosets, Teflon® AF, and benzocyclobutenes.

3. The method of claim 1, wherein the first hard mask layer and the second hard mask layer comprises one or more of silicon carbide, oxygen doped silicon carbide, nitrogen doped silicon carbide, silicon nitride, oxygen doped silicon nitride, carbon doped silicon nitride, and oxygen and carbon doped silicon nitride.

4. The method of claim 1 wherein the first hard mask layer can serve as one or more of an etch stop layer and a capping layer.

5. The method of claim 1, wherein the anti-reflective coating comprises one or more of an organic bottom anti-reflective coating material (BARC) layer, an inorganic BARC layer, and a hybrid organic-inorganic BARC layer.

6. The method of claim 1, wherein the step of depositing copper in the via and the trench comprises:
forming a barrier layer over the via and the trench;
depositing a copper seed layer over the barrier layer; and
depositing copper in the via and the trench by electrochemical deposition.

7. The method of claim 1, wherein the dummy fill has a reduced depth of about 75% or more as compared to a dummy fill formed with conventional processing.

8. A semiconductor device formed by the method of claim 1.

9. A method of making a semiconductor device, the method comprising:
forming a hard mask layer over a dielectric layer;
forming a via through the hard mask layer and the dielectric layer;
depositing an anti-reflective coating in the via and over the hard mask layer;
etching a trench through the hard mask layer;
etching a dummy fill pattern in the hard mask layer to a desired thickness;
etching the trench through the dielectric layer and the dummy fill through the hard mask layer and in the dielectric layer, wherein the dielectric layer has an etch selectivity approximately eight to ten times that of the hard mask layer;
depositing copper in the via and in the trench; and
removing excess copper using chemical mechanical polishing, wherein the dummy fill in the dielectric layer is of desired reduced depth.

10. The method of claim 9, wherein the step of etching a trench through the hard mask layer comprises;
forming a resist layer over the anti-reflective coating;
forming a trench pattern in the resist layer; and
etching a trench through the hard mask layer using the trench pattern in the resist layer.

11. The method of claim 9, wherein the dielectric layer comprises one or more of silicon oxide, organo silicate glass (OSG), fluorine-doped silicate glass (FSG), tetraethyl orthosilicate (TEOS), carbon doped silicon oxide, polyamides, fluorinated polyamides, methyl silsesquioxane (MSSQ), hydrogen silsesquioxane (HSSQ), parylene-N, parylene-F, aromatic thermosets, Teflon® AF, and benzocyclobutenes.

12. The method of claim 9, wherein the hard mask layer comprises one or more of silicon carbide, oxygen doped silicon carbide, nitrogen doped silicon carbide, silicon nitride, oxygen doped silicon nitride, carbon doped silicon nitride, and oxygen and carbon doped silicon nitride.

13. The method of claim 9, wherein the anti-reflective coating comprises one or more of an organic bottom anti-reflective coating material (BARC) layer, an inorganic BARC layer, and a hybrid organic-inorganic BARC layer.

14. The method of claim 9, wherein the step of filling the via and the trench with copper comprises:
forming a barrier layer over the via and the trench;
depositing a copper seed layer over the barrier layer; and
depositing copper in the via and the trench by electrochemical deposition.

15. The method of claim 9, wherein the dummy fill has a reduced depth of about 75% or more as compared to a dummy feature formed with conventional processing.

16. The method of claim 9, wherein the hard mask layer can serve as one or more of an etch stop layer and a capping layer.

17. A semiconductor device formed by the method of claim 9.
